(19) United States
(12) Patent Application Publication
(10) Pub. No.: US 2015/0087131 A1
(43) Pub. Date: Mar. 26, 2015

(54) METHOD FOR PROCESSING A CHIP

(71) Applicant: Infineon Technologies AG, Neubiberg (DE)

(72) Inventors: Stefan Martens, Muenchen (DE); Raimund Peichl, Hoehenkirchen-Siegertsbrunn (DE)

(73) Assignee: Infineon Technologies AG, Neubiberg (DE)

(21) Appl. No.: 14/032,223

(22) Filed: Sep. 20, 2013

(51) Int. Cl. H01L 21/78; H01L 23/544

(52) U.S. Cl. CPC H01L 21/78; H01L 23/544
USPC 438/401

(57) ABSTRACT

A method for processing a chip is provided. The method may include: providing a chip having a front side and a back side; and forming an orientation marker on the back side of the chip by forming a hole into the chip from the front side of the chip, the hole forming the orientation marker.

### TECHNICAL FIELD

Various embodiments relate to a method for processing a chip.

### BACKGROUND

During various manufacturing processes of chips, orientation markers may be crucial for placing a singularized chip on a carrier using the orientation marker for the positioning on the carrier, for instance. In particular, for the case that during any processing step only a bare back side of the chips is visible, it may be necessary for subsequent processing steps that the back side has an orientation mark.

Orientation marking of very small chip scale package (CSP), typically for e.g. diodes and/or transistors in silicon packages with a product size smaller than 1 mm² may be challenging because in case of such a product size, a single wafer typically contains more than 50,000 and even up to 600,000 units. Chip scale packages (CSP) with or without solder bumps, wherein interconnects to the application are manufactured by flat solder pads with or without a solder depot. Currently, orientation marking of chips is usually provided during various manufacturing processes by two well-known approaches, laser back side marking and back side structuring.

### SUMMARY

A method for processing a chip is provided. The method may include: providing a chip having a front side and a back side; and forming an orientation marker on the back side of the chip by forming a hole into the chip from the front side of the chip, the hole forming the orientation marker.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 illustrates a method in accordance with various embodiments;

FIG. 2 illustrates a method in accordance with various embodiments;

FIG. 3 illustrates a method in accordance with various embodiments;

FIG. 4 illustrates a method in accordance with various embodiments;

FIG. 5 illustrates a bottom view of an embodiment of a chip arrangement in accordance with various embodiments;

FIG. 6 illustrates a cross-sectional view of the embodiment shown in FIG. 5 of the chip arrangement according to various embodiments;

FIG. 7 illustrates a bottom view of an embodiment of a chip arrangement in accordance with various embodiments;

FIG. 8 illustrates a bottom view of an embodiment of a chip arrangement in accordance with various embodiments;

FIG. 9 illustrates a top view of various embodiments of a chip arrangement in accordance with various embodiments;

FIG. 10 illustrates a top view of an embodiment of a chip arrangement in accordance with various embodiments; and

FIG. 11 illustrates a bottom view of an embodiment of a chip arrangement in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Various embodiments illustratively combine the process of etching and/or plasma etching (also known as plasma dicing) in order to separate the units of the entire wafer by e.g. etching kerfs between the units and an additional etching and/or plasma etching process of etching areas within the chip area in order to obtain at least one orientation marker on each unit in one common process. In other words, the dicing and the marking of the chips may be carried out in one common process.

By way of example, the product orientation may be indicated to prevent mis-orientation of the product, e.g. a single chip, during various subsequent processes, e.g. a taping process to ensure that the product is placed with the correct orientation into the carrier tape. Usually in a taping process of chip scale packages (CSP), the packages have to be placed into the carrier tape with the pad side face-down to be manufactured with as such standard pick and place equipment and therefore, there is no visible product orientation marking once the product is placed into the carrier tape in the conventional processes.

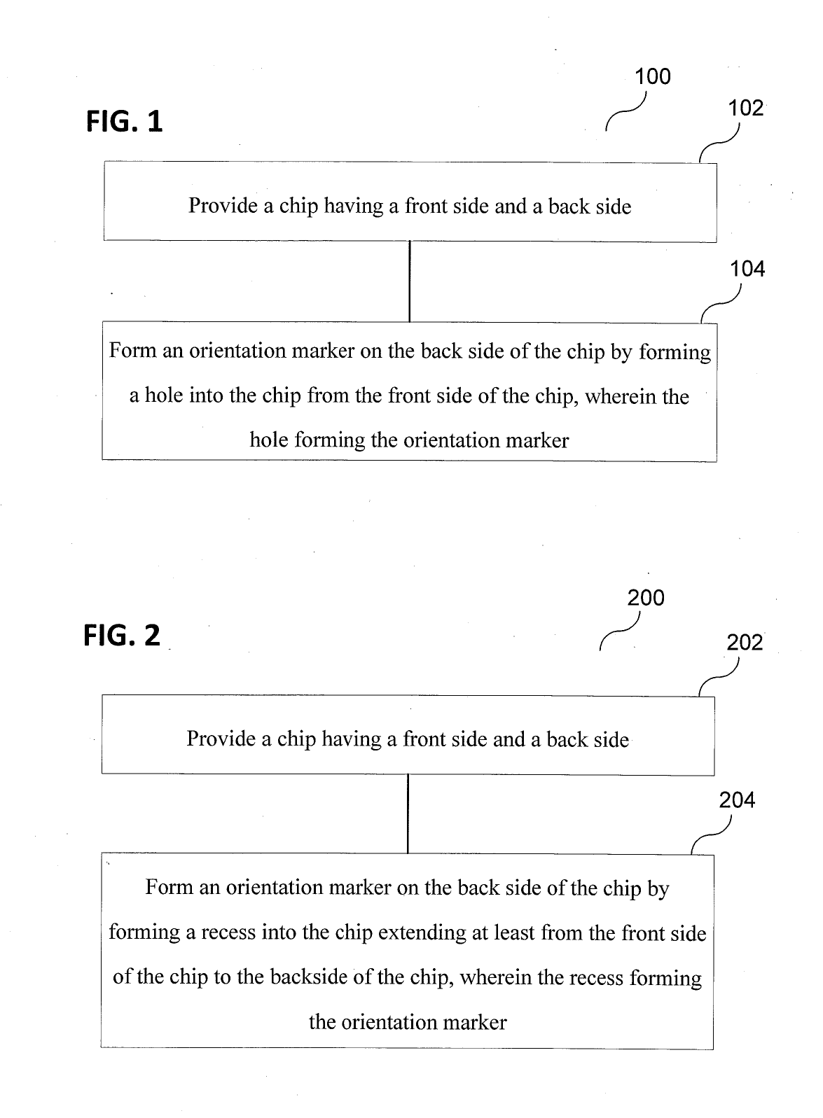

FIG. 1 shows a method 100 for processing a chip according to various embodiments. The method 100 for processing a chip may include, in 102, providing a chip having a front side and a back side, and, in 104, forming an orientation marker on the back side of the chip by forming a hole into the chip from the front side of the chip, wherein the hole may form the orientation marker.

The method 100 may further include: forming an orientation marker on the back side of the chip by forming the hole into the chip from the front side of the chip, wherein the hole may form the orientation marker and wherein forming the hole into the chip from the front side of the chip may include forming the hole into the chip starting from the front side of the chip.

The chip may be a bare chip, wherein a chip or a bare chip may also be referred to as a die or a bare die, respectively. Herein, the term “bare chip” or “bare die” designates a chip and a die, respectively, which may not yet be packaged. In other words, a bare chip or a bare die may be unpackaged during the processing of the disclosed methods herein, wherein such an assembling may be also referrred to as a chip scale package (CSP).

In various embodiments, the orientation marker may be formed on the back side of the (bare) chip by forming one or more holes into the chip from the front side of the chip, wherein the one or more holes may form the orientation marker. By way of example, the orientation marker may be formed on the back side of the chip by forming one or more holes, e.g. a plurality of holes, into the chip from the front side of the chip, wherein the one or more holes, e.g. a plurality of holes, may form the orientation marker.

In various embodiments, one or more orientation markers may be formed on the back side of the chip by forming one or more holes into the chip from the front side of the chip, wherein the one or more holes may form the one or more orientation markers. By way of example, the one or more orientation markers, e.g. a plurality of orientation markers, may be formed on the back side of the chip by forming one or more holes into the chip from the front side of the chip, wherein the one or more holes may form the one or more orientation markers, e.g. a plurality of orientation markers.

In various embodiments, one or more orientation markers may be formed on the back side of the one or more chips by forming one or more holes into the one or more chips from the front side of the one or more chips, wherein the one or more holes may form the one or more orientation markers. By way of example, the one or more orientation markers, e.g. a plurality of orientation markers, may be formed on the back side of one or more chips of a plurality of chips, e.g. on the back side of each chip of the plurality of chips, by forming one or more holes into the one or more chips of a plurality of chips, e.g. into each chip of the plurality of chips, from the front side of the one or more chips of a plurality of chips, wherein the one or more holes may form the one or more orientation markers, e.g. a plurality of orientation markers.

The at least one chip may have a front side, a back side, and one or more sidewalls, wherein the front side of the at least one chip faces a first direction and the back side of the at least one chip faces a second direction opposite to the first direction. The front side of the at least one chip may also be referred to as a top side or a first side of the chip. The front side may be a side of the at least one chip on which one or more electronic structures and/or one or more structured elements may be formed by one or more previous processes and/or may be formed by one or more subsequent processes. The back side of the at least one chip may be also referred to as a bottom side or a second side. The back side may be a side of the at least one chip which may be substantially free from one or more electronic structures or electronic components and/or structured elements.

The at least one chip may have a footprint that may be at least one of the group of geometrical shapes, wherein the group may include or consist of: a square, a rectangle, a circle, a triangle, a hexagon, a polygon, and the like.

The at least one chip may have a footprint, wherein the footprint may be the footprint of the front side and/or the back side of the at least one chip and may be in the range from about 0.2 mm² to about 20 mm², or may be in the range from about 0.01 mm² to about 10 mm², or may be in the range from about 0.1 mm² to about 1 mm², or may be in the range from about 0.1 mm² to about 0.2 mm², or may be in the range from about 0.01 mm² to about 0.1 mm².

The front side of the at least one chip may be that side where one or more electronic structures and/or structured elements may be formed by one or more processes, e.g. by one or more front end of line (FEOL) processes, such as e.g. layer deposition, patterning, doping, or heat treatment. The at least one electronic structure and/or structured element may be or include at least one of the group of electronic structures or structured elements, wherein the group may include or consist of: a diode, a transistor, a bipolar junction transistor, a field effect transistor, a resistor, a capacitor, an inductor, a thyristor, a power transistor, a power metal oxide semiconductor (MOS) transistor, a power bipolar transistor, a power field effect transistor, a power insulated gate bipolar transistor (IGBT), a MOS controlled thyristors, a silicon controlled rectifier, a power schottky diode, a silicon carbide diode, a gallium nitride device, an ASIC, a driver, a controller, a low noise amplifier, and/or a sensor.

The at least one chip may include at least one of a wafer, a part of a wafer, a substrate, a part of a substrate, a carrier, a part of a carrier and the like. The at least one chip may further include at least one of a processed wafer, a processed substrate, a processed carrier and the like.

At least the back side of the at least one chip may be formed by one or more layers of a substrate material, wherein the substrate material may be one or more of semiconductor substrate materials, as will be described below. In various embodiments, the back side and the front side may be formed by a substrate material, wherein the substrate material may be one or more of the semiconductor materials, as will be described below. Furthermore, the entire chip may be formed by a substrate material, wherein the substrate material may be one or more of the semiconductor materials, as will be described below.

The at least one chip may be formed by one or more substrates, wherein the one or more substrates may be formed by one or more semiconductor substrate materials. The at least one semiconductor substrate material may be at least one of the group of semiconductor materials, wherein the group of semiconductor materials may include or consist of: Silicon (Si), Silicon carbide (SiC), Silicon germanium (SiGe), Germanium (Ge), α-Tin (α-Sn), Boron (B), Selenium (Se), Tellurium (Te), Sulfur (S), Gallium phosphide (GaP), Gallium arsenide (GaAs), Indium phosphide (InP), Indium antimonide (InSb), Indium arsenide (InAs), Gallium antimonide (GaSb), Gallium nitride (GaN), Aluminum nitride (AlN), Indium nitride (InN), Aluminum gallium arsenide (AlₓGa₁₋ₓAs), and/or Indium gallium nitride (InₓGa₁₋ₓN). Moreover, the one or more materials of the one or more semiconductor substrates may be one or more compound semiconductors from the group of compound semiconductors of the following groups of the periodic system: II-V, II-V, II-VI, I-VII, IV-VI and/or V-VI.

The at least one chip may have a thickness, wherein the thickness may extend from the front side to the back side of the chip. In other words, the thickness of the at least one chip may extend between the top side and the bottom side.

The at least one hole may be formed by etching the at least one hole into the chip from the front side of the at least one chip.

Furthermore, the at least one hole may be formed by means of etching and/or by means of plasma etching, wherein the etching and/or the plasma etching may be applied from the front side of the at least one chip. Beside of the at least one hole within the chip, there may be formed also a pattern at the edge of the chip as will be described in more detail further below.

The at least one hole may extend at least partially from the back side to the front side of the at least one chip, and may be at least substantially free from at least chip material and/or the one or more electronic structures and/or structured elements.

The at least one hole may have a geometric body shape of at least one of the group of geometric body shapes, wherein the group may include or consist of: a cuboid, a cylinder, a cube, a prism, a paraboloid, and the like.

The footprint of the at least one hole forming the at least one orientation marker, which may be formed on the back side of the at least one chip by forming the at least one hole into the at least one chip from the front side of the at least one chip, may be formed to have at least one of the group of geometrical shapes, wherein the group may include or consist of: a circular shape, a triangular shape, a quadratic shape, a rectangular shape, a polygonal shape, a shape of a letter, a shape of a symbol, a shape of a number, and the like.

The at least one hole may have a footprint. This footprint may have an area in the range from about 10 μm² to about 10,000 μm², or e.g. in the range from about 20 μm² to about 1,000 μm².

The at least one hole may have a circular footprint, which may have a diameter, e.g. in the range from about 2 μm to about 100 μm.

The at least one hole forming the at least one orientation marker may be located at a position on the front side and/or the back side of the at least one chip, which may be substantially free from one or more electronic structures and/or structured elements that may be present due to one or more previous processes, e.g. one or more FEOL processes, or may be formed by one or more subsequent processing steps onto the at least one chip, e.g. by one or more back end of line (BEOL) processes. By way of example, the at least one orientation marker formed on the back side of the at least one chip by forming at least one hole into the at least one chip from the front side of the at least one chip may be formed into one or more corners or corner portions, at one or more edges or edge areas of the at least one chip, or the shape may be etched at the edge of the of the at least one chip, or any other desirable and/or suitable location on the front side and/or the back side of the at least one chip.

FIG. 2 shows a method 200 for processing a chip in accordance with various embodiments. The method 200 for processing the chip may include, in 202, providing a chip having a front side and a back side, and, in 204, forming an orientation marker on the back side of the chip by forming a recess into the chip extending at least from the front side of the chip to the back side of the chip, wherein the recess may form the orientation marker.

The method 200 for processing the chip may further include: forming an orientation marker on the back side of the chip by forming the recess into the chip extending at least from the front side of the chip to the back side of the chip, wherein the recess may extend into the chip from the front side of the chip to the back side of the chip, and wherein the recess may be formed into the chip from the front side of the chip along at least one edge of the chip.

The recess extending at least from the front side of the chip to the back side of the chip may be formed by means of etching. The etching may be applied from the front side of the chip.

Furthermore, the recess may extend at least from the front side of the chip to the back side of the chip and may be formed by means of etching and/or plasma etching. The etching and/or the plasma etching may be applied from the front side of the chip.

The recess may be substantially free from chip material and may be located at a position on the front side and/or the back side of the chip which may be substantially free from the at least one or more electrical structures and/or structured elements, or the shape may be etched at the edge of the of the at least one chip.

The at least one chip may be a chip having similar properties as the at least one chip according to the above discussed method 100 with respect to manufacturing, composition, materials used, quantity, dimensions (e.g. length, width, thickness or height), volume and surface sizes, shapes of the footprint, and body shapes.

The at least one orientation marker may be an orientation marker having similar properties as the at least one orientation marker according to the above discussed method 100 with respect to manufacturing, quantity, dimensions, volume and surface sizes, shapes of the footprint, body shapes, orientations, and positions on at least the front side and/or the back side of the at least one chip.

In accordance with various embodiments, the one or more recesses may be at least substantially free from at least chip material and may be located at a position on the front side and/or on the back side of the one or more chips which may be substantially free from the one or more electronic structures and/or structured elements.

The at least one recess may be formed to have a geometric body shape of at least one of the group of geometric body shapes, wherein the group may include or consist of: a cuboid, a cylinder, a cube, a prism, a paraboloid, and the like.

The footprint of the at least one recess may be formed to have at least one of the group of geometrical shapes, wherein the group may include or consist of: a circular shape, a triangular shape, a quadratic shape, a rectangular shape, a hexagonal shape, a polygonal shape, a shape of a letter, a shape of a symbol, a shape of a number, and the like.

The at least one recess may have a footprint, wherein this footprint may be in a range from about 10 μm² to about 10,000 μm², or e.g. may be in a range from about 20 μm² to about 1,000 μm², for instance.

The at least one recess may have a circular footprint, wherein this circular footprint may have a diameter. This diameter may be in the range from about 2 μm to about 100 μm.

The at least one recess may be located at a position on the front side of the at least one chip and/or the back side of the at least one chip which may be substantially free from one or more electronic structures and/or structured elements that may be present due to at least one or more previous processes, e.g. one or more FEOL processes, or may be formed by any subsequent processing step on the at least one chip, e.g. by one or more back end of line (BEOL) processes. By way of example, the at least one orientation marker may be formed in one or more corners or corner portions, at one or more edges or edge areas, or any other desirable and/or suitable location on the front side and/or the back side of the at least one chip.

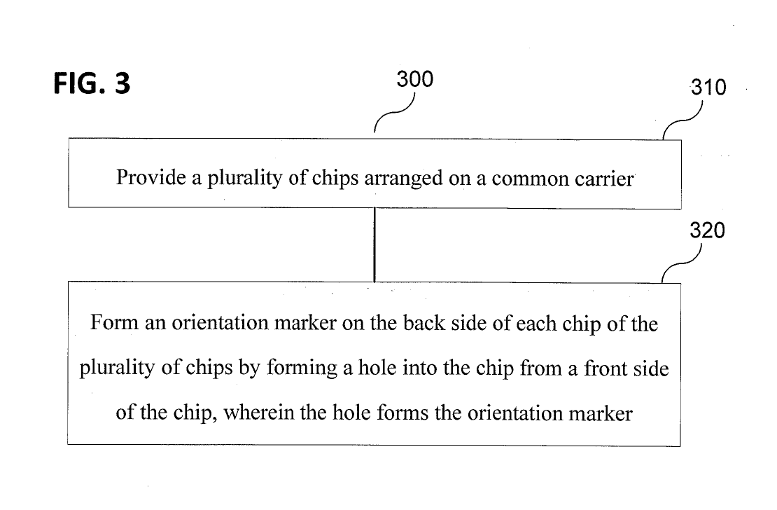

FIG. 3 shows a method 300 for processing a plurality of chips in accordance with various embodiments. The method 300 for processing a plurality of chips may include:

providing the plurality of chips arranged on a common carrier (in 310); and

forming an orientation marker on a back side of each chip of the plurality of chips by forming a hole into the chip from a front side of the chip, wherein the hole forms the orientation marker (in 320).

The method 300 for processing the plurality of chips may further include: separating at least one chip of the plurality of chips from the other chips of the plurality of chips.

Furthermore, the separating of the at least one chip may be carried out by means of an etch process.

Moreover, the etch process may be applied from the front side of the at least one chip of the plurality of chips.

Further, the separating of the at least one chip may be carried out by means of an etch process and/or a plasma etch process. The separating may be carried out in one common etch process. The separating may be carried out from the front side of the at least one chip.

The plurality of chips may be provided on a common carrier, wherein the plurality of chips may have similar properties as the at least one chip as described above.

The at least one hole as well as the at least one orientation marker formed in 320 may be a hole and an orientation marker having similar properties as the at least one orientation marker as described above.

In accordance with various embodiments, the at least one orientation marker may be formed on the back side of each chip of the plurality of chips by forming at least one hole into each chip of the plurality of chips from the front side of each chip.

In accordance with various embodiment, the at least one orientation marker may also be formed by at least one recess, e.g. a recess as described above.

The (common) carrier in 310 may have at least a front side and a back side, wherein the front side of the carrier faces in a first direction and the back side of the carrier faces in a second direction opposite to the first direction. The front side of the carrier may be also referred to as a top side or as a first side of the carrier and may be a side on which the chips may be arranged. The back side of the carrier may also be referred to as a bottom side or as a second side of the carrier, wherein the back side may be a side which is substantially free from chips.

The carrier in 310 may be formed by a wafer, a processed wafer, a substrate, a processed substrate, a semiconductor substrate or processed semiconductor substrate, e.g. which may be formed by one or more of the above discussed semiconductor materials according to method 100, a foil, and/or a plate, and the like.

The carrier may be formed by at least one of the group of materials, wherein the group may include or consist of: one or more of the semiconductor materials as have been discussed above according to method 100, ceramic materials, glass (e.g. a massive glass carrier wafer), polymers, organic polymers, metals, metal alloys, and the like.

The carrier may be formed to have at least one shape of the group of shapes, wherein the group may include or consist of: circle, triangle, square, rectangle, pentagon, hexagon, polygon, and the like.

The carrier may have, in case of a circular footprint, a diameter which may be in the range from about 10 mm to 600 mm, or may be in the range from about 50 mm to about 450 mm, or may be in the range from about 75 mm to about 300 mm, or may be in the range from about 0.5 mm to about 20 mm.

The carrier may have a thickness extending between the front side of the carrier and the back side of the carrier which may be in the range from about 100 μm to about 1 mm.

By way of example, the plurality of chips arranged on the common carrier may be arranged in an array structure onto the carrier, e.g. in rows and columns in a matrix-like arrangement.

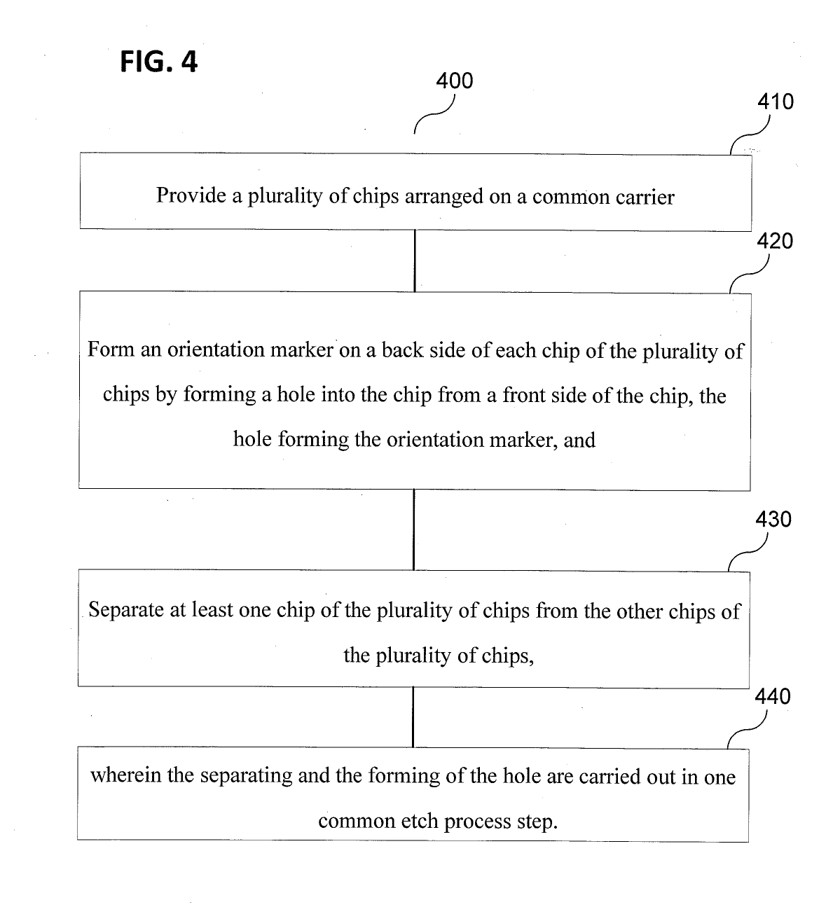

FIG. 4 shows a method 400 for processing a plurality of chips in accordance with various embodiments. The method 400 for processing a plurality of chips may include:

providing the plurality of chips arranged on a common carrier (in 410);

forming an orientation marker on a back side of each chip of the plurality of chips by forming a hole into the chip from a front side of the chip, wherein the hole forms the orientation marker at step (in 420); and

separating at least one chip of the plurality of chips from the other chips of the plurality of chips (in 430);

wherein the separating and the forming of the hole are carried out in one common etch process (in 440).

Furthermore, the method 400 for processing a plurality of chip may be carried out so that the separating of at least one chip of the plurality of chips and the forming of the hole may be carried out in one common etch process and/or in one common plasma etch process.

The common etch process and/or the common plasma etch process may be applied from the front side of the at least one chip of the plurality of chips.

The plurality of chips arranged on the common carrier may be arranged on a carrier that may be a carrier as described above with respect to the previous figures.

The plurality of chips arranged on the common carrier may be a plurality of chips wherein at least one chip of the plurality of chips having similar properties as the at least one chip as described above. The at least one orientation marker may be an orientation marker having similar properties as the at least one orientation marker as described above. Furthermore, the at least one hole may be a hole having similar properties as the at least one hole as described above.

In accordance with various embodiments, the at least one orientation marker may be formed by forming at least one hole into each chip of the plurality of chips from the front side of each chip of the plurality of chips according to the above discussed method 100 and/or by forming at least one recess into each chip of the plurality of chips extending from the front side of each chip of the plurality of chips to the back side of each chip of the plurality of chips according to the above discussed method 200, wherein the at least one hole and/or the at least one recess form the at least one orientation marker.

The method 400 for processing the plurality of chips may further include placing the singularized chip on a further carrier using the at least one orientation marker.

The method 400 may further include placing the at least one singularized chip on a further carrier using the at least one orientation marker that may be formed on the back side of each chip of the plurality of chips by forming at least one hole into the chip from the front side of each chip of the plurality of chips and/or by forming at least one recess into each chip of the plurality of chips extending at least from the front side of each chip of the plurality of chips to the back side of each chip of the plurality of chips.

The at least one singularized chip may be placed on a further carrier using the at least one orientation marker, wherein the further carrier may be formed by a wafer, a processed wafer, a substrate, a processed substrate, a semiconductor substrate or processed semiconductor substrate, e.g. which may be formed by one or more of the above discussed semiconductor materials according to method 100, a foil, and/or a plate.

The further carrier may be formed from at least one of the group of materials, wherein the group may include or consist of one or more of the semiconductor materials as have been discussed above according to method 100, ceramic materials, polymers, organic polymers, metals, metal alloys, and the like.

The further carrier may be formed to have a geometrical shape which may be at least one of the group of geometrical shapes, wherein the group may include or consist of: circle, rectangular, square, triangular, pentagon, hexagon, any polygonal, and the like.

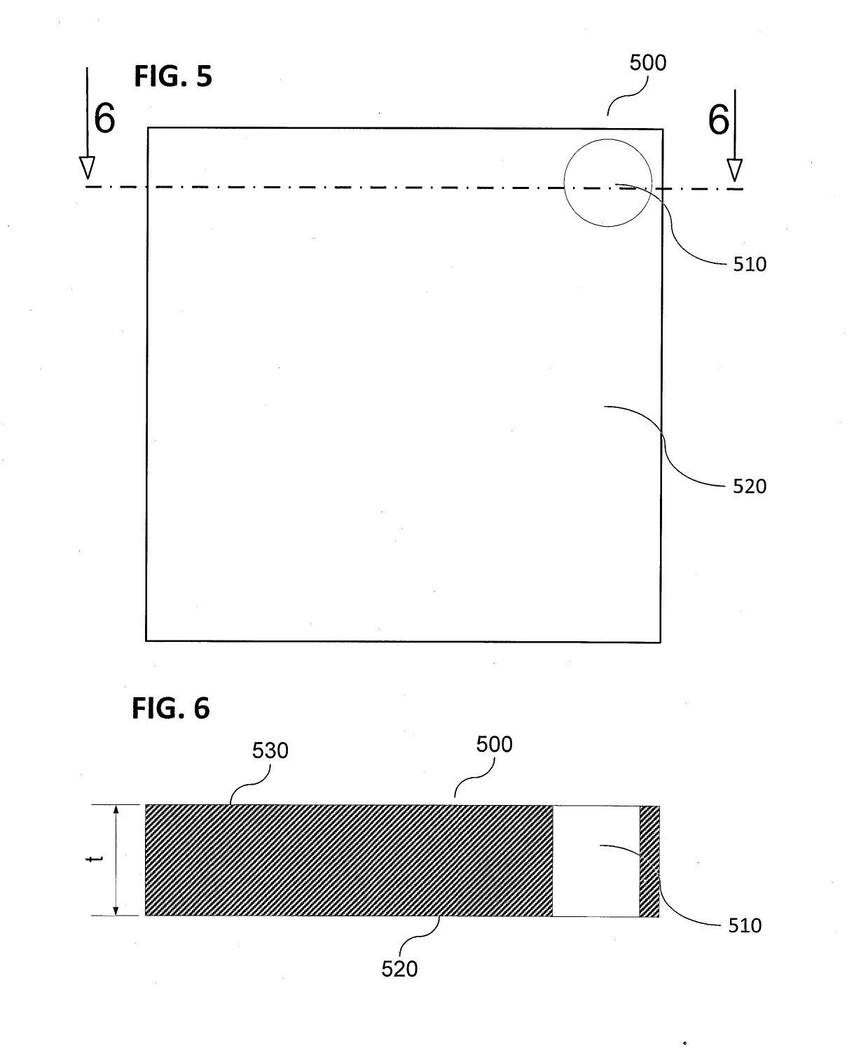

FIG. 5 shows a bottom view of an exemplary chip 500 to be processed by at least one of the above discussed methods 100, 200, 300, or 400 in accordance with various embodiments. The chip 500 may have at least one hole forming the at least one orientation marker 510 that may be formed on the back side 520 of the chip 500 by forming at least one hole into the chip 500 from the front side (which is opposite to the back side 520) of the chip 500, wherein the at least one hole may form the at least one orientation marker 510.

The exemplary chip 500 and the at least one orientation marker 510 may have similar properties as the at least one chip according to at least one of the above discussed methods 100, 200, 300 or 400.

Furthermore, the at least one hole may be a hole having similar properties as the at least one hole as described above.

It is to be understood that although only a single exemplary chip 500 is shown in FIG. 5, the embodiments are not limited to a single chip 500, but may also include a plurality of chips.

Furthermore, although only one single orientation marker 510 is shown in FIG. 5, the embodiments are not limited to exactly one orientation marker 510, but may include a plurality of orientation markers 510.

FIG. 6 shows a cross-sectional view of the chip 500 as shown in FIG. 5 in accordance with various embodiments. The chip 500 may have the at least one hole 510 forming the at least one orientation marker 510 that may be formed on the back side 520 of the chip 500 by forming at least one hole into the chip 500 from the front side 530 of the chip 500.

The front side 530 of the chip 500 may face a first direction and the back side 520 of the chip 500 may face in the opposite direction which may also be referred to as a second direction.

Further, the shape (or orientation) of the at least one hole 510 may not be limited to a 90° straight line. Moreover, the side wall angle of the at least one hole 510 may be formed having a tilted angle, wherein the angle may be in the range from about 85° to about 95°, e.g. in the range from about 87° to about 93°, e.g. in the range from about 75° to about 105°. In addition, also the side wall of the at least one hole 510 may have a topography (e.g. a pattern) which may be caused by one of the hole forming processes as discussed above, such as etching and/or plasma etching.

The chip 500 may have a thickness t, which may extend from the front side 530 to the back side 520 of the chip 500.

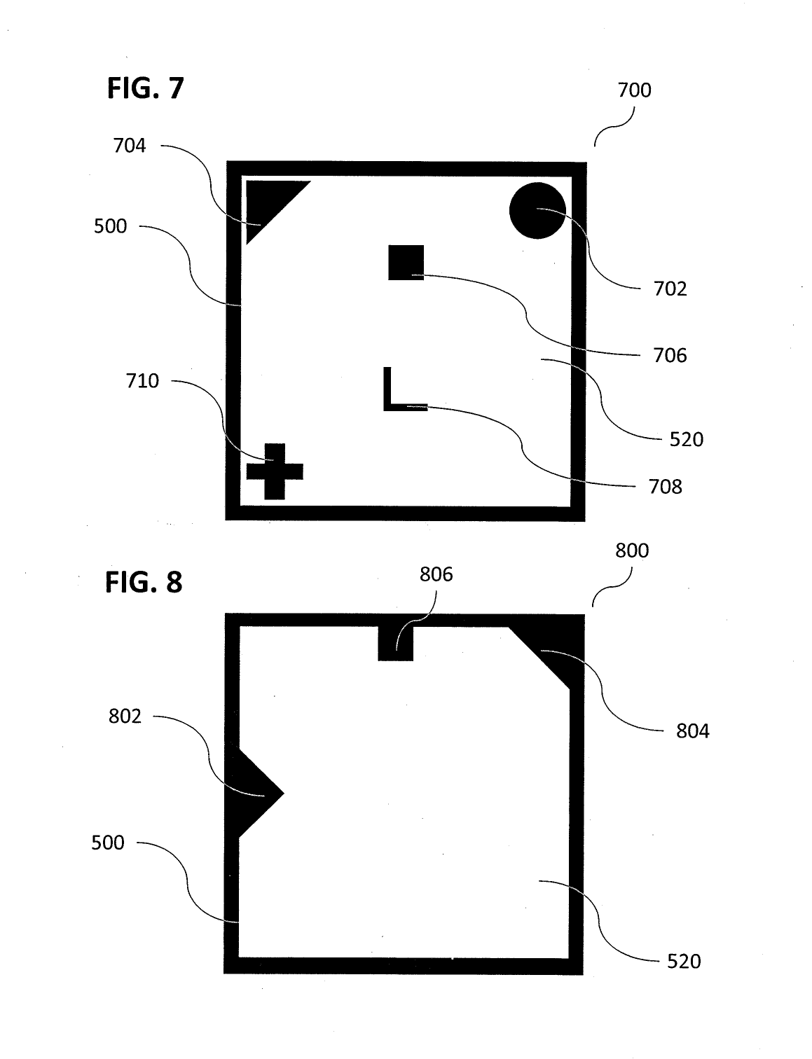

FIG. 7 shows a bottom view of an exemplary chip arrangement 700, wherein the exemplary chip arrangement is depicted as an exemplary CSP, in accordance with various embodiments. The chip arrangement 700 having various exemplary orientation markers 510 that may be formed on the back side 520 of the chip 500 by forming the at least one hole into the chip 500 from the front side 530 (not shown) of the chip 500 according to at least one of the above discussed methods 100, 200, 300, or 400.

Further, the chip arrangement 700 may include one or more chips 500. The chip arrangement 700 may have a plurality of orientation markers 510 that may be formed according to at least one of the above discussed methods 100, 200, 300, or 400 on the back side 520 of the chip 500 by forming the at least one hole 510 into the chip 500 from the front side of the chip 500 having a footprint which may be circular shaped (e.g. a first orientation marker 702 in FIG. 7), triangular shaped (e.g. a second orientation marker 704 in FIG. 7), quadratic shaped (e.g. a third orientation marker 706 in FIG. 7), L-shaped (e.g. a fourth orientation marker 708 in FIG. 7), or cross-shaped (e.g. a fifth orientation marker 710 in FIG. 7), for instance.

Although FIG. 7 illustrates the exemplary footprints of various orientation markers 510 that may be circular shaped, triangular shaped, quadratic shaped, L-shaped, or cross-like shaped, a shape of a letter, a shape of a symbol, a shape of a number, but they are not limited to these shapes. Also any other polygonal shaped footprint of orientation markers may be provided.

FIG. 8 shows a bottom view of a chip arrangement 800 in accordance with various embodiments, wherein the chip arrangement 800 is shown as an exemplary CSP, having a plurality orientation markers that may be formed on the edge of the chip 500 or on the back side 520 of the chip 500 by forming at least one recess into the chip 500 extending at least from the front side to the back side of the chip 500.

The one or more orientation markers 810 may be formed in accordance to at least one of the above discussed methods 100, 200, 300, or 400.

The plurality of orientation markers 810 may have various footprints which may be triangular shaped (e.g. a first orientation marker 802 and a second orientation marker 804 in FIG. 8) or quadratic shaped (e.g. a third orientation marker 806 in FIG. 8), for instance.

The at least one hole (which may be a recess in other embodiments) may be formed to be substantially free from chip material of the at least one chip 500 of the chip arrangement 800.

Further, the chip arrangement 800 may include one or more chips 500. The at least one chip 500 of the chip arrangement 800 may be a chip having similar properties as the at least one chip as described above.

Although FIG. 8 illustrates various footprints of different orientation markers 802, 804, 806, that may be triangular shaped or quadratic shaped, it is to be understood, that also any other polygonal shaped footprint of orientation markers may be provided in various embodiments.

The orientation marker 802, 804, 806, may be formed on the back side 520 of the chip 500 by forming the hole (or recess) into the chip 500 extending at least from the front side of the chip 500 to the back side 520 of the chip 500, wherein the hole or recess may be formed along at least one edge of the chip 500.

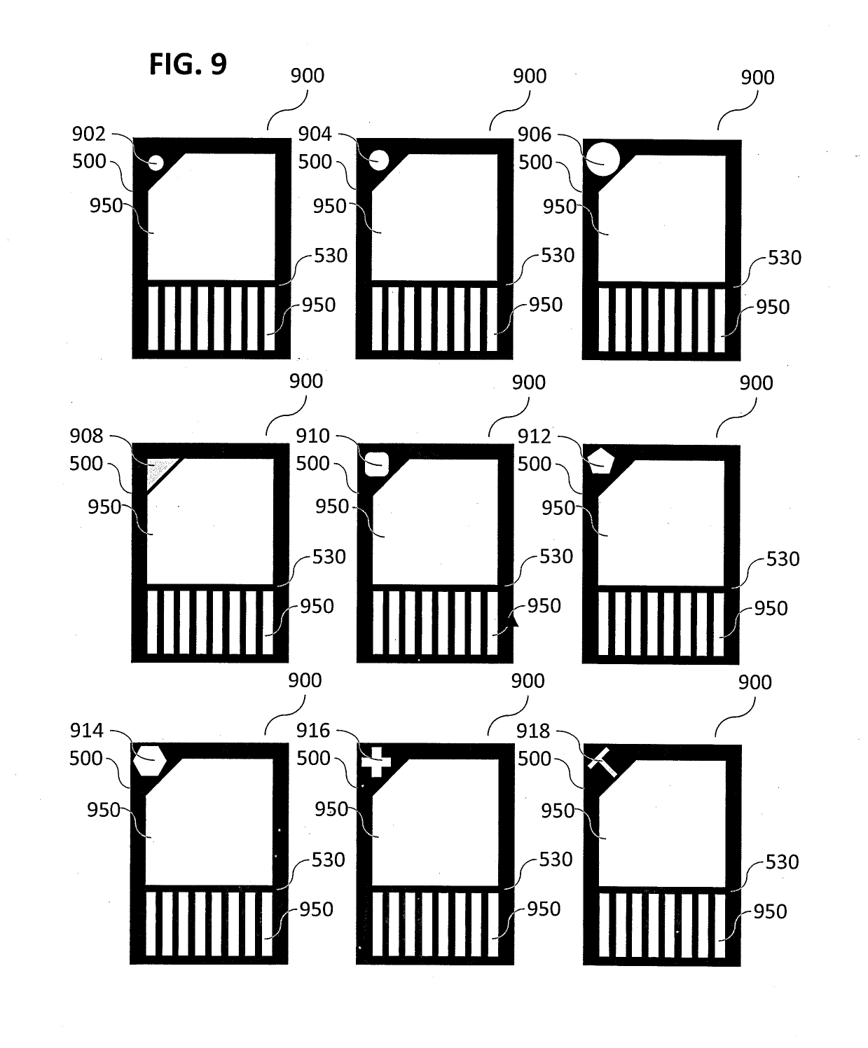

FIG. 9 shows a top view of various exemplary chip arrangements 900 in accordance with various embodiments, wherein the chip arrangements 900 are shown as CSP with a diagonal pad corner in accordance with various embodiments. Moreover, as shown in FIG. 9, the diagonal pad corner may be at least substantially free from any of the at least one electronic structure 950 and/or any structured element 950 that may be disposed on top of the front side 530 of the chip 500.

The chip arrangements 900 may include one or more chips 500. The chips 500 of the chip arrangements 900 may be chips having similar properties as the at least one chip as described above.

The at least one orientation marker 510 may be an orientation marker having similar properties as the at least one orientation marker as described above.

The at least one hole and/or recess may be a hole and/or a recess having similar properties as the at least one hole and/or recess according to at least one of the above discussed methods 100, 200, 300, or 400 with respect to manufacturing, quantity, dimensions, volume and surface sizes, shapes of the footprint, body shapes, orientations, and positions on at least the front side and/or the back side of the at least one chip.

The exemplary orientation markers 510 of the exemplary chip arrangements 900 may be formed on the back side of the exemplary chips 500 by forming at least one hole into the exemplary chips 500 from the front side 530 of the exemplary chips 500 of the exemplary chip arrangement 900 and/or by forming at least one recess into the exemplary chips 500 of the exemplary chip arrangements 900 from the front side 530 of the exemplary chips 500 of the exemplary chip arrangements 900 to the back side of the exemplary chips 500 of the exemplary chip arrangements 900 in accordance with at least one of the above discussed methods 100, 200, 300 or 400.

The chip arrangements 900 shown in FIG. 9 may have differently shaped areas of the orientation markers 510 in the diagonal pad corner, which may be substantially free from the at least one electronic structure 950 and/or the at least one structured element 950. By way of example, the various orientation markers 510 may have a footprint which may be e.g. different sized circular shaped (e.g. first orientation markers 902, 904, 906, which may have different diameters), e.g. triangular shaped (e.g. second orientation markers 908), e.g. rectangular shaped with rounded corners (e.g. third orientation markers 910), e.g. pentagonal shaped (e.g. fourth orientation markers 912), e.g. hexagonal shaped (e.g. fifth orientation markers 914), e.g. cross-like shaped (e.g. sixth orientation markers 916), e.g. T-like shaped (e.g. seventh orientation markers 918), and the like.

Although various shapes of orientation markers 902, 904, 906, 908, 910, 912, 914, 916, 918, are illustrated in FIG. 9, it is to be understood, that also any other polygonal shaped footprint of exemplary orientation markers 902, 904, 906, 908, 910, 912, 914, 916, 918, may be formed on the back side of the exemplary chip 500 of the chip arrangement 900 by forming at least one hole into the chip 500 of the chip arrangement 900 from the front side 530 of the chip 500 of the chip arrangement 900 and/or by forming at least one recess into the chip 500 of the chip arrangement 900 extending at least from the front side 530 of the chip 500 to the back side of the chip 500.

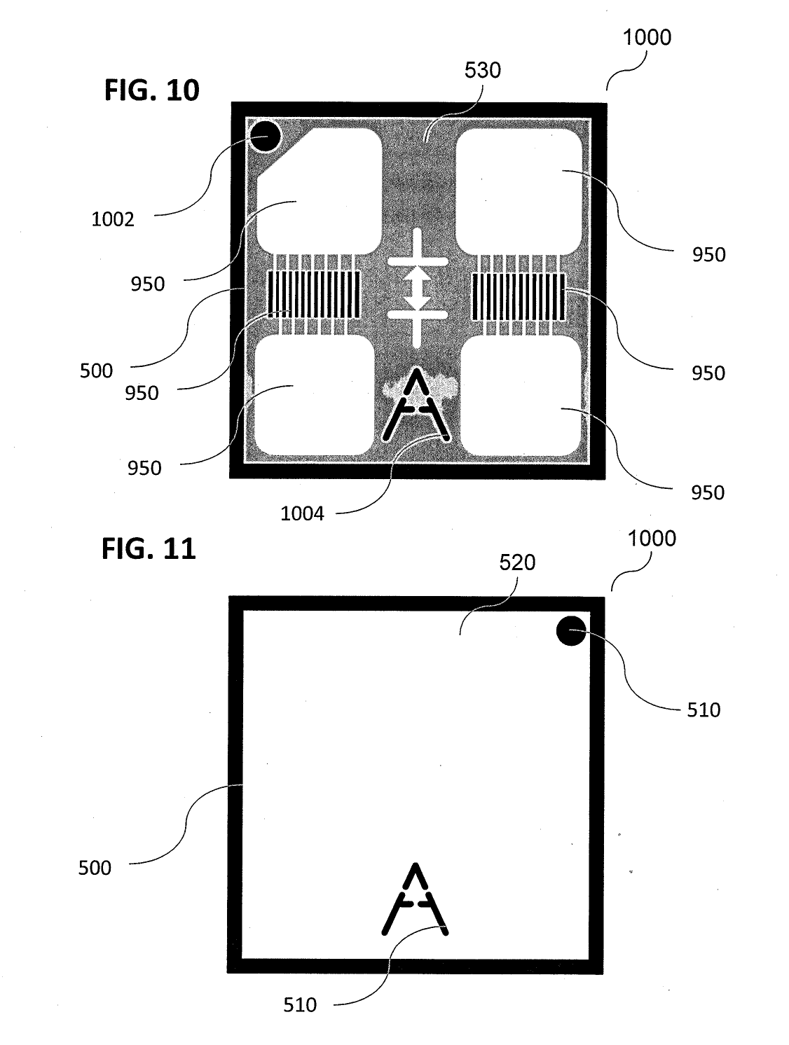

FIG. 10 shows a top view of a chip arrangement 1000 in accordance with various embodiments, wherein the chip arrangement 1000 is shown as an exemplary CSP with one diagonal pad corner, having two different orientation markers 1002, 1004. Moreover, as shown in FIG. 10, the diagonal pad corner may be substantially free from the at least one electronic structure 950 and/or the at least one structured element 950 on top of the front side 530 of the chip 500 of the chip arrangement 1000.

Although the both orientation markers 1002, 1004, shown in FIG. 10 are shown as being formed on the back side of the chip 500 of the chip arrangement 1000 by forming at least one hole into the chip 500 of the chip arrangement 1000 from the front side the chip 500 of the chip arrangement 1000 according to one of the above mentioned methods 100, 200, 300, or 400, it is to be understood, that orientation markers also may be formed on the back side of the chip of such an chip arrangement by forming at least one recess into the chip 500 of such a chip arrangement extending at least from the front side 530 of the chip 500 of an chip arrangement to the back side of the chip 500 of a chip arrangement.

The at least one chip 500 of the chip arrangement 1000 may be a chip 500 having similar properties as the at least one chip as described above. The at least one orientation marker formed into the chip 500 of the chip arrangement 1000 may be an orientation marker having similar properties as the at least one orientation marker as described above. The at least one hole formed into the chip 500 of the chip arrangement 1000 may be a hole or a recess having similar properties as the at least one hole or recess as described above.

The chip arrangement 1000 shown in FIG. 10 may have differently shaped areas of the orientation markers 510, e.g. one as shown in the right upper corner of the exemplary chip arrangement 1000 in FIG. 10, e.g. in the right upper diagonal pad corner, which may be substantially free from the at least one electronic structure 950 and/or the at least one structured element 950 and the other one is shown in the lower middle of the chip arrangement 1000 in FIG. 10 between two of the pad structures 950. By way of example, the orientation marker 510 in the diagonal pad corner may be formed as a circular shaped orientation marker 510 and the other one between the two pad structures may be formed as an A-shaped orientation marker 510. Both orientation markers 510 may be formed in accordance with at least one of the above discussed methods 100, 200, 300, or 400.

Although two footprint shapes of the orientation markers 510 are illustrated in FIG. 10, it is to be understood, that also any other polygonal shaped footprint of an exemplary orientation marker 510 may be formed on the back side of the exemplary chip 500 of the exemplary chip arrangement 1000.

FIG. 11 shows a bottom view of the chip arrangement 1000 of FIG. 10 in accordance with various embodiments.

In various embodiments, a method for processing a chip may include providing a chip having a front side and a backside; and forming an orientation marker on the back side of the chip by forming a hole into the chip from the front side of the chip, wherein the hole forms the orientation marker.

In various embodiments, the hole may be formed by means of etching.

In various embodiments, the hole may be formed by means of plasma etching.

In various embodiments, the forming the hole into the chip from the front side of the chip may include forming the hole into the chip starting from the front side of the chip.

In various embodiments, the at least one hole may be formed to have a geometric body shape of at least one of the group of geometric body shapes, the group consisting of: a cuboid; a cylinder; a cube; a prism; and a paraboloid.

In various embodiments, a footprint of the at least one hole formed into the chip from the front side of the chip may be in the range from about 20 μm² to about 10,000 μm².

In various embodiments, a method for processing a chip may include: providing a chip having a front side and a backside; and forming the orientation marker on a back side of the chip by forming a recess into the chip extending at least from a front side of the chip to a back side of the chip, wherein the recess forming the orientation marker.

In various embodiments, the recess is formed along at least one edge of the chip.

In various embodiments, the recess may be formed by means of etching, e.g. by means of plasma etching.

In various embodiments, the at least one recess may be formed to have a geometric body shape of at least one of the group of geometric body shapes, the group consisting of: cuboid; cylinder; cube; prism; and paraboloid.

In various embodiments, a footprint of the at least one recess formed into the chip from the front side of the chip may be in the range from about 20 μm² to about 10000 μm².

In various embodiments, a method for processing a plurality of chips may include: providing a plurality of chips arranged on a common carrier; and forming an orientation marker on a back side of each chip of the plurality of chips by forming a hole into the chip from a front side of the chip, wherein the hole forms the orientation marker.

In various embodiments, the method may further include: separating at least one chip of the plurality of chips from the other chips of the plurality of chips.

In various embodiments, the separating of the at least one chip may be carried out by means of an etch process, wherein the etch process may be applied from the front side of the chip.

In various embodiments, the separating of the at least one chip may be carried out by means of the etch process, wherein the etch process may be a plasma etch process.

In various embodiments, the separating and the forming of the hole may be carried out in one common etch process step.

In various embodiments, the method may further include: placing the singularized chip on a further carrier using the orientation marker.

In various embodiments, the at least one hole is formed to have a geometric body shape of at least one of the group of geometric body shapes, the group consisting of: cuboid; cylinder; cube; prism; and paraboloid.

In various embodiments, the footprint of the at least one hole formed into the chip from the front side of the chip may be in the range from about 20 μm² to about 10,000 μm².

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for processing a chip, the method comprising:
providing a chip having a front side and a back side;
forming an orientation marker on the back side of the chip by forming a hole into the chip from the front side of the chip, the hole forming the orientation marker.

2. The method of claim 1,
wherein the hole is formed by means of etching.

3. The method of claim 2,
wherein the hole is formed by means of plasma etching.

4. The method of claim 1,
wherein forming the hole into the chip from the front side of the chip comprises forming the hole into the chip starting from the front side of the chip.

5. The method of claim 1,
wherein the at least one hole is formed to have a geometric body shape of at least one of the group of geometric body shapes, the group consisting of:
cuboid;
cylinder;
cube;
prism; and
paraboloid.

6. The method of claim 1,
wherein a footprint of the at least one hole formed into the chip from the front side of the chip is in the range from about 20 μm² to about 10,000 μm².

7. A method for processing a chip, the method comprising:
providing a chip having a front side and a back side;
forming an orientation marker on the back side of the chip by forming a recess into the chip extending at least from a front side of the chip to the back side of the chip, the recess forming the orientation marker.

8. The method of claim 7,
wherein the recess is formed into the chip from the front side along at least one edge of the chip.

9. The method of claim 7,
wherein the recess is formed by means of etching.

10. The method of claim 9,
wherein the recess is formed by means of plasma etching.

11. The method of claim 7,
wherein the at least one recess is formed to have a geometric body shape of at least one of the group of geometric body shapes, the group consisting of:
cuboid;
cylinder;
cube;
prism; and
paraboloid.

12. The method of claim 7,
wherein a footprint of the at least one recess formed into the chip from the front side of the chip is in the range from about 20 μm² to about 10000 μm².

13. A method for processing a plurality of chips, the method comprising:
providing the plurality of chips arranged on a common carrier; and
forming an orientation marker on a back side of each chip of the plurality of chips by forming a hole into the chip from a front side of the chip, the hole forming the orientation marker.

14. The method of claim 13, further comprising:
separating at least one chip of the plurality of chips from the other chips of the plurality of chips.

15. The method of claim 14,
wherein separating of the at least one chip is carried out by means of an etch process.

16. The method of claim 15,
wherein the etch process is applied from the front side of the chip.

17. The method of claim 15,
wherein the etch process is a plasma etch process.

18. The method of claim 15,
wherein the separating and the forming of the hole are carried out in one common etch process step.

19. The method of claim 14, further comprising:
placing the singularized chip on a further carrier using the orientation marker.

20. The method of claim 14,
wherein the at least one hole is formed to have a geometric body shape of at least one of the group of geometric body shapes, the group consisting of:
cuboid;
cylinder;
cube;
prism; and
paraboloid.

21. The method of claim 14,
wherein a footprint of the at least one hole formed into the chip from the front side of the chip is in the range from about 20 μm² to about 10,000 μm².
